(19) United States
(12) Patent Application Publication
(10) Pub. No.: US 2026/0143712 A1
(43) Pub. Date: May 21, 2026

(54) MEMORY DEVICE AND METHOD OF MANUFACTURING THE MEMORY DEVICE

(71) Applicant: SK hynix Inc., Icheon-si Gyeonggi-do (KR)

(72) Inventors: Jun Hyuk LEE, Icheon-si Gyeonggi-do (KR); Deung Kak YOO, Icheon-si Gyeonggi-do (KR)

(73) Assignee: SK hynix Inc., Icheon-si Gyeonggi-do (KR)

(21) Appl. No.: 19/189,534

(22) Filed: Apr. 25, 2025

(30) Foreign Application Priority Data
Nov. 21, 2024 (KR) 10-2024-0167472

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

A memory device and a method of manufacturing the memory device are described. The memory device includes a source structure formed over a substrate, a gate stack formed over the source structure and including conductive layers alternately stacked with insulating layers, and a channel structure extending through the gate stack in a first direction and extending into the source structure. The channel structure includes a first channel layer extending in the first direction and located in the gate stack and the source structure, a memory layer surrounding a sidewall of the first channel layer and located between the gate stack and the first channel layer, and a second channel layer located between the source structure and the first channel layer and surrounding the sidewall of the first channel layer that extends into the source structure.

### CROSS-REFERENCE TO RELATED APPLICATION

The present application claims priority under 35 U.S.C. § 119(a) to Korean patent application number 10-2024-0167472 filed on Nov. 21, 2024, in the Korean Intellectual Property Office, which application is incorporated herein by reference in its entirety.

### BACKGROUND

### 1. Technical Field

The present disclosure generally relate to an electronic device, including but not limited to a memory device and a method of manufacturing the memory device.

### 2. Related Art

A non-volatile memory device retains stored data even when supplied power is interrupted. An increase in integration density of a two-dimensional non-volatile memory device in which memory cells are formed in a single layer over a substrate is limited. Three-dimensional non-volatile memory devices in which memory cells are stacked in a vertical direction over a substrate provide greater integration density.

A three-dimensional non-volatile memory device includes interlayer insulating layers alternately stacked with gate electrodes, channel layers passing through the interlayer insulating layers and the gate electrodes, and memory cells stacked along the channel layers. Various structures and manufacturing methods improve the operational reliability of three-dimensional non-volatile memory devices.

### SUMMARY

According to an embodiment of the present disclosure, a memory device may include a source structure formed over a substrate, a gate stack formed over the source structure and including conductive layers alternately stacked with insulating layers alternately, and a channel structure extending through the gate stack in a first direction and extending into the source structure. The channel structure may include a first channel layer extending in the first direction and located within the gate stack and the source structure, a memory layer surrounding a sidewall of the first channel layer and located between the gate stack and the first channel layer, and a second channel layer located between the source structure and the first channel layer and surrounding the sidewall of the first channel layer that extends into the source structure.

According to an embodiment of the present disclosure, a memory device may include a source structure formed over a substrate, a gate stack formed over the source structure and including conductive layers alternately stacked with insulating layers alternately stacked, and a channel structure extending through the gate stack in a first direction and extending into the source structure. The channel structure may include an first channel layer extending in the first direction and located in the gate stack, a second channel layer in contact with a second surface of the first channel layer and extending in the first direction into the source structure, and a memory layer surrounding a sidewall of the first channel layer and a sidewall of the second channel layer, wherein the second channel layer extends through the memory layer and extends in a horizontal direction to contact the source structure.

According to an embodiment of the present disclosure, a method of manufacturing a memory device may include: forming a source structure by sequentially stacking a first source layer, a sacrificial layer, and a second source layer; forming a stacked structure including first material layers alternately stacked with second material layers over the source structure; forming a plurality of channel holes extending through the stacked structure, the second source layer, and the sacrificial layer; forming a first channel layer and a memory layer surrounding the first channel layer in each of the plurality of channel holes; forming a slit extending through the stacked structure and the second source layer to expose the sacrificial layer; exposing the memory layer extending into the source structure by removing the sacrificial layer exposed through the slit; exposing the first channel layer by removing the memory layer; forming a second channel layer in contact with the first channel layer; and forming a third source layer in contact with the second channel layer in a space resulting from removal of the sacrificial layer.

### BRIEF DESCRIPTION OF THE DRAWINGS

FIG. 1 is a cross-sectional view illustrating structure of a memory device according to an embodiment of the present disclosure;

FIG. 2 to FIG. 10 are cross-sectional views illustrating a memory device formed utilizing a method of manufacturing a memory device according to an embodiment of the present disclosure;

FIG. 11 is a block diagram illustrating a configuration of a memory system according to an embodiment of the present disclosure;

FIG. 12 is a block diagram illustrating a configuration of a memory system according to an embodiment of the present disclosure;

FIG. 13 is a block diagram illustrating a configuration of a computing system according to an embodiment of the present disclosure; and

FIG. 14 is a block diagram illustrating a computing system according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. The drawings are not necessarily drawn to scale. Examples or embodiments in accordance with the concepts may be carried out in various forms, and the scope of the present disclosure is not limited to the examples or embodiments described in this specification.

When one component is identified as “connected” to another component, the components may be connected directly or through at least one intervening component between the components. When two components are identified as “directly connected,” one component is directly connected to the other component without an intervening component between the two components.

The cross-hatching throughout the figures illustrates corresponding or similar areas between the figures rather than indicating the materials associated with the areas.

Terms such as “vertical,” “horizontal,” “bottom,” “below,” “over,” “on,” “sidewall,” “upper,” “uppermost,” “lower,” “lowermost,” “high,” “level,” and other terms implying relative spatial relationship or orientation are utilized only for the purpose of ease of description or reference to a drawing and are not otherwise limiting.

Various embodiments are directed to a memory device in which errors, caused by defects in a channel structure, are reduced or mitigated during an erase operation and a method of manufacturing the memory device.

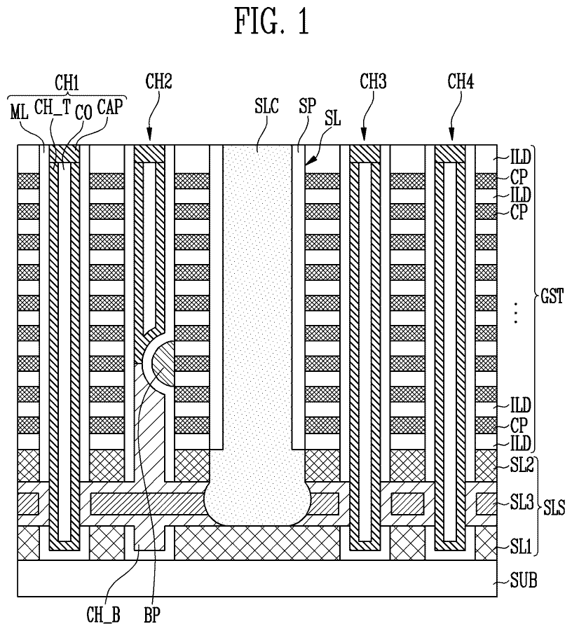

FIG. 1 is a cross-sectional view illustrating structure of a memory device according to an embodiment of the present disclosure.

Referring to FIG. 1, the memory device includes a source structure SLS, a gate stack GST, a plurality of channel structures CH1 to CH4, and a slit SL.

The source structure SLS is located between a substrate SUB and the gate stack GST. The source structure SLS includes a first source layer SL1, a second source layer SL2, and a third source layer SL3. The first source layer SL1 is located adjacent to the substrate SUB, the second source layer SL2 is located adjacent to the gate stack GST, and the third source layer SL3 is located between the first source layer SL1 and the second source layer SL2. An upper surface and a lower surface of the third source layer SL3 are in direct contact with lower channel layers CH_B of the plurality of channel structures CH1 to CH4. For example, the lower channel layer CH_B extends in a horizontal direction, or a first direction I, and is located along an interface between the first source layer SL1 and the third source layer SL3 and along an interface between the third source layer SL3 and the second source layer SL2.

The third source layer SL3 is located over the first source layer SL1, with the lower channel layer CH_B of the plurality of channel structures CH1 to CH4 extending and located within the third source layer SL3.

The gate stack GST is located over the source structure SLS. The gate stack GST includes interlayer insulating layers ILD alternately stacked with conductive layers CP. The conductive layers CP may be word lines connected to memory cells and select lines connected to select transistors. For example, one or more conductive layers CP located lowermost among the conductive layers CP may be source select lines connected to source select transistors. One or more conductive layers CP located uppermost among the conductive layers CP may be drain select lines connected to drain select transistors. The conductive layers CP other than the conductive layers CP that form the source select line and the drain selection line may be word lines.

The plurality of channel structures CH1 to CH4 extends through the gate stack GST in a vertical direction, also referred to as a third direction III, to extend to the source structure SLS. Each of the plurality of channel structures CH1 to CH4 may include a core insulating layer CO, an upper channel layer CH_T, a memory layer ML, a capping layer CAP, and the lower channel layer CH_B.

For example, the core insulating layer CO extends in the vertical direction and may include an insulating material such as an oxide. The upper channel layer CH_T surrounds a sidewall and a lower surface of the core insulating layer CO and may include a semiconductor material such as silicon (Si) or germanium (Ge). The memory layer ML surrounds a sidewall of the upper channel layer CH_T and extends in the vertical direction into the source structure SLS. The memory layer ML includes at least one of a charge blocking layer, a data storage layer, and a tunnel insulating layer. For example, the tunnel insulating layer surrounds the sidewall of the upper channel layer CH_T, the data storage layer surrounds a sidewall of the tunnel insulating layer, and the charge blocking layer surrounds a sidewall of the data storage layer. The data storage layer may include a floating gate, a charge trap material, polysilicon, a nitride, a variable resistance material, a phase change material, nanodots, and so forth. The capping layer CAP is located over or on top of each of the plurality of channel structures CH1 to CH4 and contacts the upper channel layer CH_T. The capping layer CAP may include a conductive material. A sidewall of the capping layer CAP is surrounded by the memory layer ML.

The upper channel layer CH_T of each of a plurality of channel structures CH1, CH3, and CH4 of the plurality of channel structures CH1 to CH4 contacts the lower channel layer CH_B at a lower section of the upper channel layer CH_T that extends into the source structure SLS. For example, the lower channel layer CH_B extends through the memory layer ML at a lower section of each of the plurality of channel structures CH1, CH3, and CH4 that extends into the source structure SLS and is in direct contact with the sidewall of the upper channel layer CH_T.

In one or more of the plurality of channel structures CH1 to CH4, for example, in the channel structure CH2, a by-product BP remains on a sidewall of the gate stack GST. The by-product BP is generated during or results from an etching process that forms a hole extending through the gate stack GST to form the channel structures CH1 to CH4. During a process of forming the upper channel layer CH_T, the by-product BP remaining on the sidewall of the hole prevents or mitigates the formation of the upper channel layer CH_T in a section of the hole that is below the by-product BP. When the formation of the upper channel layer CH_T in the section of the hole below the by-product BP is prevented or mitigated, the lower channel layer CH_B fills a lower section of the hole and directly contacts the upper channel layer CH_T. The lower channel layer CH_B directly contacts a lower surface of the upper channel layer CH_T and extends in the vertical direction into the source structure SLS. The lower channel layer CH_B extends in the horizontal direction in the source structure SLS, extends through the memory layer ML, and directly contacts the third source layer SL3.

Select transistors or memory cells are located in regions where the plurality of channel structures CH1 to CH4 intersect the conductive layers CP. Select transistors and memory cells sharing one upper channel layer CH_T or sharing one upper channel layer CH_T and one lower channel layer CH_B form one memory string. The memory string includes one or more drain select transistors, a plurality of memory cells, and one or more source select transistors connected in series.

The slit SL extends through the gate stack GST in the vertical direction and extend into the source structure SLS. The slit SL includes a source line contact SLC that extends through the gate stack GST in the vertical direction to connect to the source structure SLS, and a spacer SP that physically and electrically separates the gate stack GST from the source line contact SLC. The source line contact SLC may be a conductive layer including polysilicon, metal, or the like. The spacer SP may include an insulating layer and may include a single layer or multiple layers.

The source line contact SLC extends into the source structure SLS and may be directly connected to the third source layer SL3. The third source layer SL3 may be directly connected to the lower channel layer CH_B. The lower channel layer CH_B may directly contact a sidewall of the upper channel layer CH_T that extends into the source structure SLS or the lower channel layer CH_B may extend into the gate stack GST and directly contact the lower surface of the upper channel layer CH_T of the channel structure CH2.

The third source layer SL3 may include doped polysilicon doped with an n-type impurity. The lower channel layer CH_B may be undoped polysilicon into which no impurity is doped, doped polysilicon with a lower doping concentration of the n-type impurity than the third source layer SL3, or doped polysilicon doped with a p-type impurity.

In an embodiment of the present disclosure, the third source layer SL3 is not in direct contact with the upper channel layer CH_T because the lower channel layer CH_B is located between the third source layer SL3 and the upper channel layer CH_T. A junction overlap region of the upper channel layer CH_T corresponding to the source select transistor may be formed to stably generate a Gate Induced Drain Leakage (GIDL) current during an erase operation. When the upper channel layer CH_T is not formed at the lower section of the hole due to formation of a by-product BP generated during the etching process that formed the hole, the lower channel layer CH_B is embedded along the lower section of the hole to suppress or mitigate the occurrence of defects.

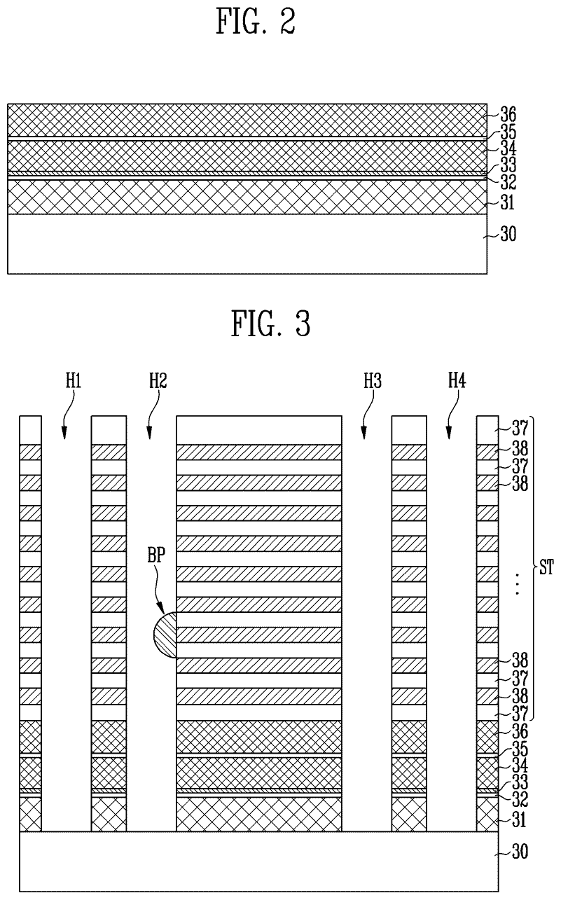

FIG. 2 to FIG. 10 are cross-sectional views illustrating a memory device formed utilizing a method of manufacturing the memory device according to an embodiment of the present disclosure.

Referring to FIG. 2, a first source layer 31, a first buffer layer 32, a second buffer layer 33, a sacrificial layer 34, a third buffer layer 35, and a second source layer 36 re sequentially formed over or on a base 30.

The base 30 is a semiconductor substrate, an insulating layer, or the like. The first source layer 31 may include a polysilicon layer. The first source layer 31 may include an n-type or p-type impurity. The first buffer layer 32 may include an oxide layer. The second buffer layer 33 may include a nitride layer. The sacrificial layer 34 may include a polysilicon layer. The third buffer layer 34 may include an oxide layer. The second source layer 36 may include a polysilicon layer. The second source layer 36 may include the n-type or p-type impurity.

Referring to FIG. 3, a stacked structure ST is formed over or on the second source layer 36. The stacked structure ST includes first material layers 37 alternately stacked with second material layers 38. The second material layers 38 may include a material having high etch selectivity with respect to the etch selectivity of the first material layers 37. In one example, the first material layers 37 are insulating layers that may include an oxide or the like, and the second material layers 38 are sacrificial layers that may include a nitride or the like. For example, the second material layers 38 may be conductive layers including polysilicon, tungsten, or the like, and the first material layers 37 may be insulating layers including an oxide or the like.

The stacked structure ST, the second source layer 36, the third buffer layer 35, the sacrificial layer 34, the second buffer layer 33, and the first buffer layer 32 are etched to form a plurality of channel holes H1 to H4 extending in the vertical direction. Each of the plurality of channel holes H1 to H4 extends into the first source layer 31.

During an etching process that forms the plurality of channel holes H1 to H4 as described with respect to FIG. 3, a by-product BP may be generated and remain on a sidewall of the stacked structure ST adjacent to one or more of the plurality of channel holes, for example, the channel hole H2.

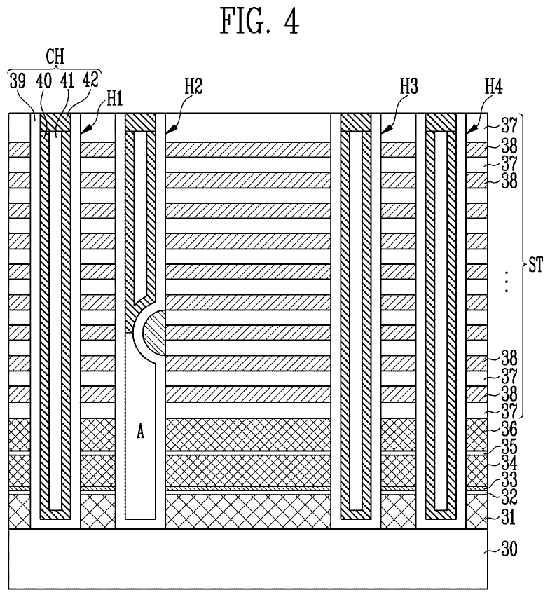

Referring to FIG. 4, a channel structures CH is formed in each of the plurality of channel holes H1 to H4. A method of forming the channel structures CH is described.

Memory layers 39 are formed in the plurality of channel holes H1 to H4. Each of the memory layers 39 may include at least one of a charge blocking layer, a data storage layer, and a tunnel insulating layer. For example, the charge blocking layer, the data storage layer, and the tunnel insulating layer are sequentially formed on a sidewall of the stacked structure ST adjacent to each of the plurality of channel holes H1 to H4.

Upper channel layers 40 are formed in the plurality of channel holes H1 to H4. The upper channel layers 40 may include a semiconductor material such as silicon (Si) and germanium (Ge). A section of the channel hole H2 including the by-product BP, shown in FIG. 3, that remains on the sidewall has a decreased width due to the by-product BP. As a result, the upper channel layer 40 may not be formed in a lower section of the channel hole H2 and the lower section may include an empty space A.

A central region of each of the plurality of channel holes H1 to H4 is filled with a core insulating layer 41.

A section of the upper channel layer 40 and a section of the core insulating layer 41 are etched to form a recess region, and the recess region is filled with a conductive material to form a capping layer 42. The capping layer 42 may include a polysilicon layer.

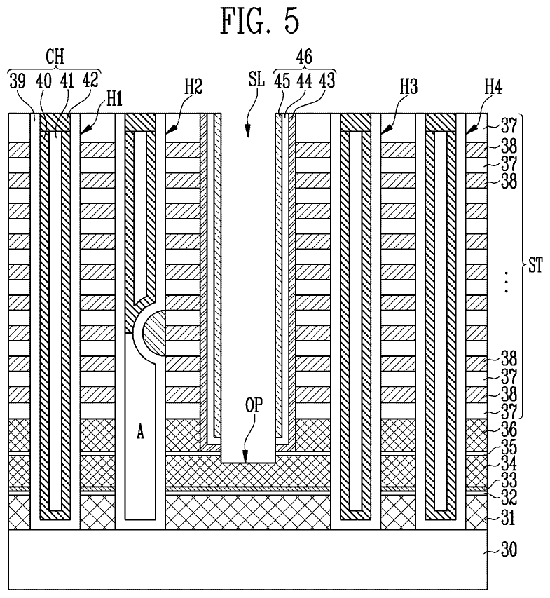

Referring to FIG. 5, the slit SL is formed. The slit SL extends through the stacked structure ST and the second source layer 36 in the vertical direction. The slit SL may be formed by sequentially etching the stacked structure ST and the second source layer 36 such that a section of the third buffer layer 35 is exposed.

A protective layer 46 may be formed on a sidewall of the stacked structure ST and an upper surface of the third buffer layer 35 that are exposed through the slit SL. The protective layer 46 has multiple layers in the example of FIG. 5. For example, the protective layer 46 includes a first protective layer 43, a second protective layer 44, and a third protective layer 45. The first protective layer 43 and the third protective layer 45 may each include a nitride layer, and the second protective layer 44 may include an oxide layer.

The protective layer 46 and the third buffer layer 35 formed adjacent to a bottom of the slit SL are etched to form an opening OP through which a section of the sacrificial layer 34 is exposed.

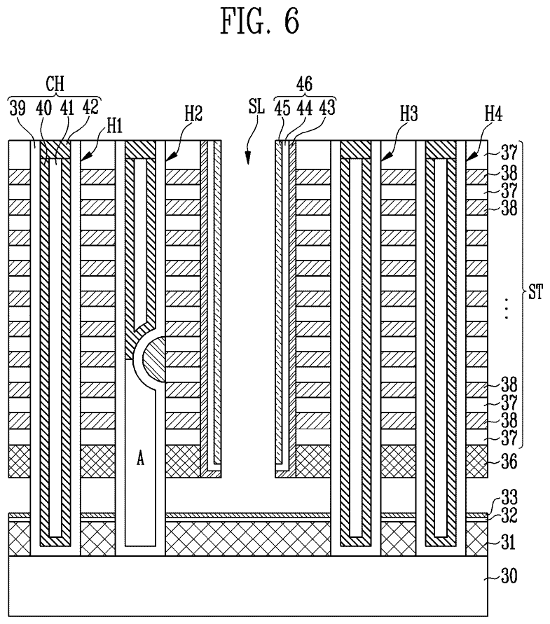

Referring to FIG. 6, the sacrificial layer 34 shown in FIG. 5 is removed. For example, the sacrificial layer is removed by introducing a material capable of etching the sacrificial layer through the slit SL. Because the sacrificial layer is removed, a section of a sidewall of the memory layer 39 of each of the channel structures CH is exposed.

The third buffer layer 35 shown in FIG. 5 is removed.

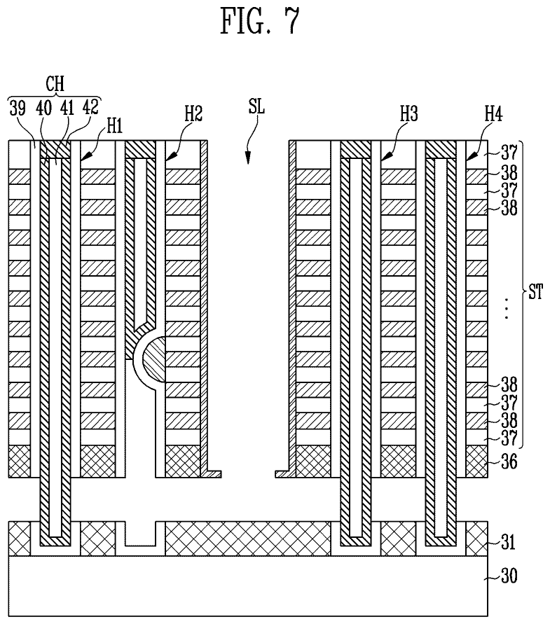

Referring to FIG. 7, the exposed section of the sidewall of the memory layer 39 is etched to expose a section of a sidewall of the upper channel layer 40 of each of the channel structures CH. During an etching process of the memory layer 39, the third protective layer 45 shown in FIG. 6, the second protective layer 44 shown in FIG. 6, the second buffer layer 33 shown in FIG. 6, and the first buffer layer 32 shown in FIG. 6 are removed, and may be removed during the same process.

The empty space A shown in FIG. 6 within the former channel hole H2 is exposed during the etching process of the memory layer 39.

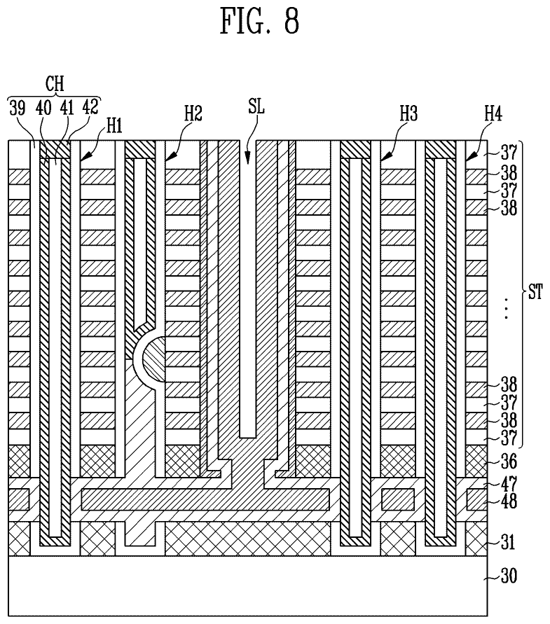

Referring to FIG. 8, a lower channel layer 47 and a third source layer 48 are formed in a space resulting from removal of the sacrificial layer through the slit SL. The lower channel layer 47 may directly contact the exposed section of the sidewall of the upper channel layer 40 and may fill the empty space A shown in FIG. 6 and may directly contact the upper channel layer 40 formed within the channel hole H2.

The lower channel layer 47 may include undoped polysilicon into which no impurity is doped, doped polysilicon with a lower doping concentration of an n-type impurity than the third source layer 48, or doped polysilicon doped with a p-type impurity. The third source layer 48 may include doped polysilicon doped with the n-type impurity.

A heat treatment process may be performed to diffuse a section of the n-type impurity included in the third source layer 48 into the lower channel layer 47. The section of the n-type impurity may diffuse through the lower channel layer 47 into the upper channel layer 40 that contacts the lower channel layer 47.

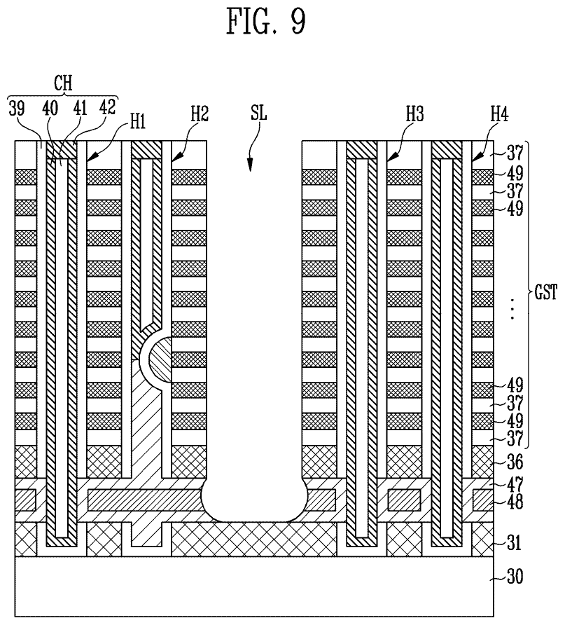

Referring to FIG. 9, the third source layer 48 and the lower channel layer 47 formed in the slit SL are removed by etching. The first protective layer 43 shown in FIG. 8 is removed to expose the second material layers 38.

Second material layers exposed through the slit SL are replaced by third material layers 49. For example, the second material layers are removed and spaces resulting from removal of the second material layers are filled with conductive layers to form the third material layers 49. A structure including the first material layers 37 and the third material layers 49 forms the gate stack GST.

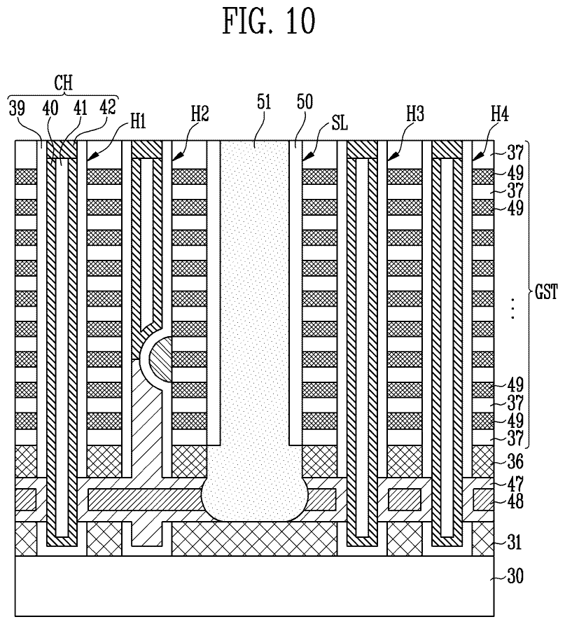

Referring to FIG. 10, a spacer 50 is formed on surfaces of the first material layers 37 and surfaces of the third material layers 49 that are exposed through the slit SL. The spacer 50 may include an insulating layer.

A source line contact 51 is formed by filling the slit SL with a conductive layer. The source line contact 51 may directly contact the third source layer 48 and may directly contact the first source layer 31 and the second source layer 36. The source line contact 51 may include polysilicon, metal, or the like.

The source line contact 51 may be a conductive layer including polysilicon, metal, or the like. The spacer 50 may include an insulating layer and may have a single layer or multiple layers.

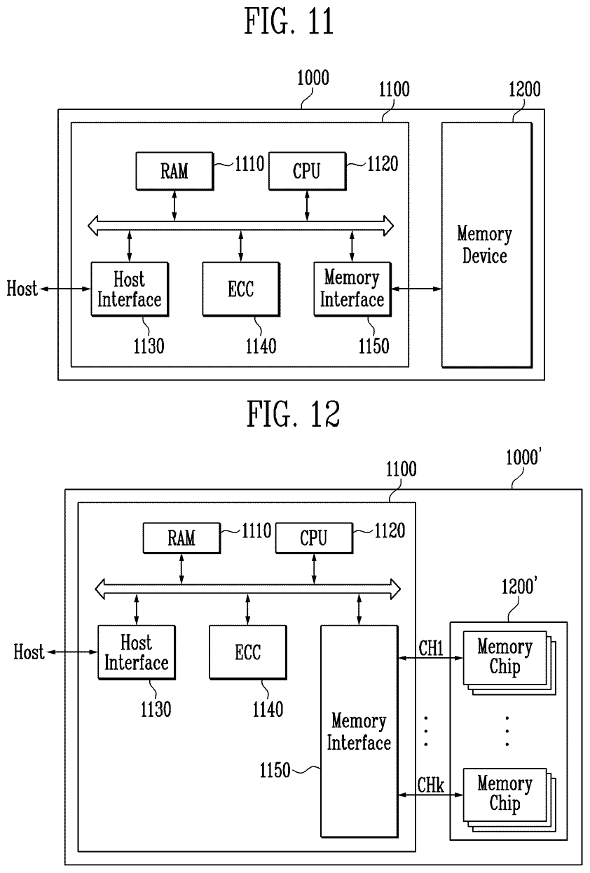

FIG. 11 is a block diagram illustrating a configuration of a memory system 1000 according to an embodiment of the present disclosure.

Referring to FIG. 11, the memory system 1000 includes a memory device 1200 and a controller 1100.

The memory device 1200 stores data information with various data formats such as a text format, a graphical format, and a software code format. The memory device 1200 may be a non-volatile memory device. The memory device 1200 includes the structure described with reference to FIG. 1, and the memory device 1200 is manufactured utilizing the method described with reference to FIG. 2 to FIG. 10.

The controller 1100 is connected to a host and the memory device 1200 and is configured to access the memory device 1200 in response to a request from the host. For example, the controller 1100 controls read, write, erase, and background operations of the memory device 1200.

The controller 1100 includes Random Access Memory (RAM) 1110, a Central Processing Unit (CPU) 1120, a host interface 1130, an Error Correction Code (ECC) circuit 1140, a memory interface 1150, and so forth.

The RAM 1110 may be used as operational memory of the CPU 1120, cache memory between the memory device 1200 and the host, buffer memory between the memory device 1200 and the host, and so forth. The RAM 1110 alternately include Static Random Access Memory (SRAM), Read Only Memory (ROM), and so forth.

The CPU 1120 controls the overall operation of the controller 1100. For example, the CPU 1120 operates according to firmware such as a Flash Translation Layer (FTL) stored in the RAM 1110.

The host interface 1130 interfaces with the host. For example, the controller 1100 communicates with the host through at least one of various interface protocols such as a Universal Serial Bus (USB) protocol, a Multi-Media Card (MMC) protocol, a Peripheral Component Interconnect (PCI) protocol, a PCI-Express (PCI-E) protocol, an Advanced Technology Attachment (ATA) protocol, a Serial-ATA protocol, a Parallel-ATA protocol, a Small Computer System Interface (SCSI) protocol, an Enhanced Small Disk Interface (ESDI) protocol, an Integrated Drive Electronics (IDE) protocol, a private protocol, and so forth.

The ECC circuit 1140 uses an Error Correction Code (ECC) to detect and correct errors in data read from the memory device 1200.

The memory interface 1150 interfaces with the memory device 1200. For example, the memory interface 1150 includes a NAND interface or a NOR interface.

The controller 1100 may include buffer memory (not illustrated) that temporarily stores data. The buffer memory temporarily stores data for transfer to an external device through the host interface 1130 or data for transfer from the memory device 1200 through the memory interface 1150. The controller 1100 may include ROM that stores code data to interface with the host.

FIG. 12 is a block diagram illustrating a configuration of a memory system 1000′ according to an embodiment of the present disclosure.

Referring to FIG. 12, the memory system 1000′ includes a memory device 1200′ and the controller 1100. The controller 1100 includes the RAM 1110, the CPU 1120, the host interface 1130, the ECC circuit 1140, the memory interface 1150, and so forth.

The memory device 1200′ may be a non-volatile memory device. The memory device 1200′ includes the structure described with reference to FIG. 1 and is manufactured utilizing the method described with reference to FIG. 2 to FIG. 10.

The memory device 1200′ is a multi-chip package including a plurality of memory chips. The plurality of memory chips are divided into a plurality of groups that communicate with the controller 1100 through corresponding first channel CH1 to kth channel CHk. Memory chips included in a single group communicate with the controller 1100 through a common channel. The memory system 1000′ may be modified such that a single memory chip is connected to a single channel.

Because the memory device 1200′ is formed as a multi-chip package, data storage capacity and driving speed of the memory system 1000′ may be enhanced or improved.

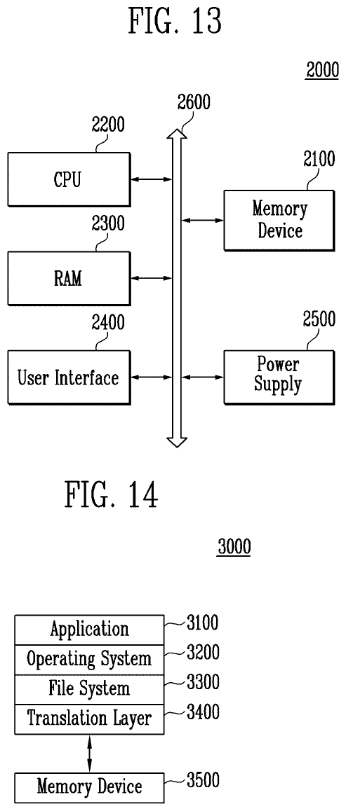

FIG. 13 is a block diagram illustrating a configuration of a computing system 2000 according to an embodiment of the present disclosure.

Referring to FIG. 13, the computing system 2000 includes a memory device 2100, a CPU 2200, RAM 2300, a user interface 2400, a power supply 2500, a system bus 2600, and so forth.

The memory device 2100 stores data provided via the user interface 2400, data processed through the CPU 2200, and so forth. The memory device 2100 is electrically connected to the CPU 2200, the RAM 2300, the user interface 2400, the power supply 2500, and so forth through the system bus 2600. For example, the memory device 2100 may be connected to the system bus 2600 via a controller (not illustrated), alternatively, directly connected to the system bus 2600. When the memory device 2100 is connected to the system bus 2600, functions of the controller may be performed by the CPU 2200 and the RAM 2300.

The memory device 2100 may be a non-volatile memory device. The memory device 2100 includes the structure described with reference to FIG. 1 and is manufactured utilizing the method described with reference to FIG. 2 to FIG. 10.

As described with reference to FIG. 12, the memory device 2100 is a multi-chip package with a plurality of memory chips.

The computing system 2000 with the configuration of FIG. 1 is one of various elements of an electronic device such as a computer, an Ultra Mobile PC (UMPC), a workstation, a net-book, a Personal Digital Assistant (PDA), a portable computer, a web tablet, a wireless phone, a mobile phone, a smartphone, an e-book, a Portable Multimedia Player (PMP), a game console, a navigation device, a black box, a digital camera, a three-dimensional television, a digital audio recorder, a digital audio player, a digital picture recorder, a digital picture player, a digital video recorder, a digital video player, a device capable of transmitting/receiving information in an wireless environment, one of various electronic devices for forming a home network, one of various electronic devices for forming a computer network, one of various electronic devices for forming a telematics network, an RFID device, and so forth.

FIG. 14 is a block diagram illustrating a computing system 3000 according to an embodiment of the present disclosure.

Referring to FIG. 14, the computing system 3000 includes a software layer that has an operating system 3200, an application 3100, a file system 3300, and a translation layer 3400. The computing system 3000 includes a hardware layer such as a memory device 3500.

The operating system 3200 manages software and hardware resources of the computing system 3000. The operating system 3200 controls program execution for a central processing unit. The application 3100 includes various application programs executed by the computing system 3000. The application 3100 may be a utility executed through the operating system 3200.

The file system 3300 refers to a logical structure configured to manage data and files present in the computing system 3000. The file system 3300 organizes files or data stored in the memory device 3500 according to given rules. The file system 3300 depends on the operating system 3200 used in the computing system 3000. For example, when the operating system 3200 is a Microsoft Windows-based system, the file system 3300 may be a File Allocation Table (FAT), an NT file system (NTFS), or the like. In addition, when the operating system 3200 is a Unix/Linux-based system, the file system 3300 may be an extended file system (EXT), a Unix File System (UFS), a Journaling File System (JFS), and so forth.

FIG. 14 illustrates the operating system 3200, the application 3100, and the file system 3300 in separate blocks. The application 3100 and the file system 3300 may alternatively be included in the operating system 3200.

The translation layer 3400 translates an address into a suitable form for the memory device 3500 in response to a request from the file system 3300. For example, the translation layer 3400 translates a logical address, generated by the file system 3300, into a physical address of the memory device 3500. Mapping information of the logical address and the physical address are stored in an address translation table. For example, the translation layer 3400 may be a Flash Translation Layer (FTL), a Universal Flash Storage Link Layer (ULL), and so forth.

The memory device 3500 may be a non-volatile memory device. The memory device 3500 includes the structure described with reference to FIG. 1 and is manufactured utilizing the method described with reference to FIG. 2 to FIG. 10.

The computing system 3000 with the configuration of FIG. 1 is divided into an operating system layer that is operated in an upper level region and a controller layer that is operated in a lower level region. The application 3100, the operating system 3200, and the file system 3300 may be included in the operating system layer, and may be driven through operational memory of the computing system 3000. The translation layer 3400 may be included in the operating system layer or the controller layer.

According to embodiments of the present disclosure, erase operation characteristics of a memory device may be improved by reducing or mitigating the increase in impurity concentration in a channel layer at a lower section of a channel structure of the memory device.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A memory device comprising:
a source structure formed over a substrate;
a gate stack formed over the source structure and including conductive layers alternately stacked with insulating layers; and
a channel structure extending through the gate stack in a first direction and extending into the source structure;
wherein the channel structure includes:
a first channel layer extending in the first direction and located within the gate stack and the source structure;
a memory layer surrounding a sidewall of the first channel layer and located between the gate stack and the first channel layer; and
a second channel layer located between the source structure and the first channel layer and surrounding the sidewall of the first channel layer that extends into the source structure.

2. The memory device of claim 1, wherein the source structure includes:
a first source layer and a second source layer formed between the substrate and the gate stack; and
a third source layer located between the first source layer and the second source layer.

3. The memory device of claim 2, wherein the second channel layer extends in a second direction and is located between the first source layer and the third source layer and between the second source layer and the third source layer.

4. The memory device of claim 2, wherein the third source layer includes doped polysilicon doped with an n-type impurity.

5. The memory device of claim 4, wherein the second channel layer includes undoped polysilicon.

6. The memory device of claim 4, wherein the second channel layer includes doped polysilicon with a lower doping concentration of the n-type impurity than a doping concentration of the third source layer or doped polysilicon doped with a p-type impurity.

7. The memory device of claim 2, wherein the third source layer is electrically connected to the first channel layer through the second channel layer.

8. The memory device of claim 1, further comprising a source line contact extending through the gate stack in the first direction and connected to the source structure.

9. The memory device of claim 8, further comprising a spacer surrounding a sidewall of the source line contact.

10. A memory device comprising:
a source structure formed over a substrate;
a gate stack formed over the source structure and including conductive layers alternately stacked with insulating layers; and
a channel structure extending through the gate stack in a first direction and extending into the source structure;
wherein the channel structure includes:
a first channel layer extending in the first direction and located in the gate stack;
a second channel layer in contact with a second surface of the first channel layer and extending in the first direction into the source structure; and
a memory layer surrounding a sidewall of the first channel layer and a sidewall of the second channel layer; and
wherein the second channel layer extends through the memory layer and extends in a second direction to contact the source structure.

11. The memory device of claim 10, wherein the source structure includes:
a first source layer and a second source layer formed between the substrate and the gate stack; and
a third source layer located between the first source layer and the second source layer.

12. The memory device of claim 11, wherein the second channel layer extends in the second direction and is located between the first source layer and the third source layer and between the second source layer and the third source layer.

13. The memory device of claim 12, wherein the third source layer includes doped polysilicon doped with an n-type impurity.

14. The memory device of claim 13, wherein the second channel layer includes undoped polysilicon.

15. The memory device of claim 13, wherein the second channel layer includes doped polysilicon with a lower doping concentration of the n-type impurity than a doping concentration of the third source layer or doped polysilicon doped with a p-type impurity.

16. The memory device of claim 11, wherein the third source layer is electrically connected to the first channel layer through the second channel layer.

17. The memory device of claim 10, further comprising a source line contact extending through the gate stack in the first direction and connected to the source structure.

18. The memory device of claim 10, further comprising a core insulating layer extending in the first direction within the first channel layer.

19. A method of manufacturing a memory device, the method comprising:
forming a source structure by sequentially stacking a first source layer, a sacrificial layer, and a second source layer;
forming a stacked structure including first material layers alternately stacked with second material layers over the source structure;
forming a plurality of channel holes extending through the stacked structure, the second source layer, and the sacrificial layer;
forming a first channel layer and a memory layer surrounding the first channel layer in each of the plurality of channel holes;
forming a slit extending through the stacked structure and the second source layer to expose the sacrificial layer;
exposing the memory layer extending into the source structure by removing the sacrificial layer exposed through the slit;
exposing the first channel layer by removing the memory layer;
forming a second channel layer in contact with the first channel layer; and
forming a third source layer in contact with the second channel layer in a space resulting from removal of the sacrificial layer.

20. The method of claim 19, wherein the third source layer includes doped polysilicon doped with an n-type impurity.

21. The method of claim 20, wherein the second channel layer includes undoped polysilicon.

22. The method of claim 21, wherein the second channel layer includes doped polysilicon with a lower doping concentration of the n-type impurity than a doping concentration of the third source layer or doped polysilicon doped with a p-type impurity.

23. The method of claim 19, further comprising performing a heat treatment process to diffuse, into the second channel layer, an impurity included in the third source layer.
